(19) United States
(12) Patent Application Publication
(10) Pub. No.: US 2017/0250372 A1
(43) Pub. Date: Aug. 31, 2017

(54) DISPLAY DEVICE, AND METHOD AND APPARATUS FOR MANUFACTURING THE SAME

(71) Applicant: Japan Display Inc., Minato-ku (JP)

(72) Inventors: Toshio TOJO, Minato-ku (JP); Hideki OZAWA, Minato-ku (JP); Yuki HAMADA, Minato-ku (JP)

(73) Assignee: Japan Display Inc., Minato-ku (JP)

(21) Appl. No.: 15/416,064

(22) Filed: Jan. 26, 2017

(30) Foreign Application Priority Data
Feb. 26, 2016 (JP) 2016-036011

(51) Int. Cl. H01L 51/52; H01L 51/50; H01L 27/32; H01L 51/00; H01L 51/56

(52) U.S. Cl. CPC H01L 51/5253; H01L 51/0025; H01L 51/001; H01L 51/0021; H01L 51/0029; H01L 51/5225; H01L 51/56; H01L 27/3211; H01L 51/5221; H01L 51/52; H01L 51/5036; H01L 51/5012; H01L 27/3244

(57) ABSTRACT

A method for manufacturing a display device includes a first step of placing a substrate having a lower electrode formed thereon in a vacuum environment; a second step of forming in a vacuum an organic layer that includes a light emitting layer and covers the lower electrode; a third step of forming in a vacuum an upper electrode that covers the organic layer; a fourth step of forming in a vacuum a sealing layer that covers the upper electrode; and a cleaning step of cleaning the substrate after end of the first step before end of the fourth step.

### CROSS-REFERENCE TO RELATED APPLICATION

The present application claims priority from Japanese application JP2016-036011 filed on Feb. 26, 2016, the content of which is hereby incorporated by reference into this application.

### BACKGROUND OF THE INVENTION

1. Field of the Invention

The present invention relates to a method for manufacturing a display device, a display device, and an apparatus for manufacturing a display device.

2. Description of the Related Art

In a display device such as an organic EL (Electro Luminescence) display device, etc., there is a case in which a light emitting device, such as an organic light emitting diode (OLED) etc., is controlled using a switching element, such as a transistor, etc., to display an image. In the above, an organic light emitting diode may be manufactured in a vacuum as organic material for forming an organic light emitting diode may be deteriorated due to invasion of water, oxygen, etc.

Japanese Patent Laid-open Publication No. 2015-072770 describes an organic electro-luminescence device in which an OLED layer is formed in contact with an anode, an inorganic bank, and an organic planarization film.

In manufacturing an organic light emitting diode in a vacuum, the inside of a vacuum chamber should be kept clean. However, fine foreign matter may be mixed into the vacuum chamber via a deposition mask or a feeding mechanism. With foreign matter mixed into an organic light emitting diode, flickering pixels may be caused, which decreases the yield.

### SUMMARY OF THE INVENTION

The present invention aims to provide a method for manufacturing a display device, a display device, and an apparatus for manufacturing a display device for preventing decrease in the yield due to foreign matter mixed.

According to the present invention, there is provided a method for manufacturing a display device including a first step of placing a substrate having a lower electrode formed thereon in a vacuum environment; a second step of forming in a vacuum an organic layer that includes a light emitting layer and covers the lower electrode; a third step of forming in a vacuum an upper electrode that covers the organic layer; a fourth step of forming in a vacuum a sealing layer that covers the upper electrode; and a cleaning step of cleaning the substrate after end of the first step before end of the fourth step.

According to the present invention, there is provided a display device including a substrate; a plurality of pixels formed on the substrate; a lower electrode provided to each of the plurality of pixels; a pixel separation film formed on the substrate, configured to cover an end portion of the lower electrode so as to leave a middle part of the lower electrode exposed, and configured to define the plurality of pixels; an organic layer being in contact with the portion of the lower electrode exposed from the pixel separation film, positioned on the pixel separation film, and including a light emitting layer; an upper electrode formed on the organic layer; and a sealing layer formed on the upper electrode, wherein the upper electrode has a hole formed on a surface thereof in contact with the sealing layer.

According to the present invention, there is provided an apparatus for manufacturing a display device including a vacuum introduction unit for placing a substrate having a lower electrode formed thereon in a vacuum environment; an organic layer forming unit connected to the vacuum introduction unit via a first convey mechanism, for forming in a vacuum an organic layer that includes a light emitting layer and covers the lower electrode on the substrate; an upper electrode forming unit connected to the organic layer forming unit via a second convey mechanism, for forming in a vacuum an upper electrode that covers the organic layer; a sealing layer forming unit connected to the upper electrode forming unit via a third convey mechanism, for forming in a vacuum a sealing layer that covers the upper electrode; and a cleaning unit connected to at least one of the organic layer forming unit, the upper electrode forming unit, and the sealing layer forming unit via a fourth convey mechanism, for cleaning the substrate.

### BRIEF DESCRIPTION OF THE DRAWINGS

FIG. 1 is a perspective view showing an organic EL display device according to an embodiment of the present invention;

FIG. 2 is a wiring diagram of an organic EL panel according to an embodiment of the present invention; FIG. 3 is a circuit diagram of a pixel of an organic EL panel according to an embodiment of the present invention;

FIG. 4 is a schematic diagram showing a laminated structure of a pixel of an organic EL panel according to an embodiment of the present invention;

FIG. 5 is a cross sectional view of a pixel of an organic EL panel according to an embodiment of the present invention;

FIG. 6 is a flowchart showing a method for manufacturing an organic EL display device according to an embodiment of the present invention;

FIG. 7 is a flowchart showing a cleaning process of a method for manufacturing an organic EL display device according to an embodiment of the present invention;

FIG. 8 shows first foreign matter and second foreign matter to be removed according to a method for manufacturing an organic EL display device according to an embodiment of the present invention;

FIG. 9 shows a cleaning process of a manufacturing method of an organic EL display device according to an embodiment of the present invention;

FIG. 10 is a cross sectional view of an organic EL panel according to an embodiment of the present invention;

FIG. 11 is a schematic diagram showing a first spray nozzle used in a cleaning process of a method for manufacturing an organic EL display device according to an embodiment of the present invention;

FIG. 12 is a block diagram showing a structure of an apparatus for manufacturing an organic EL display device according to an embodiment of the present invention; and

FIG. 13 is a schematic diagram showing a spray unit of an apparatus for manufacturing an organic EL display device according to an embodiment of the present invention.

### DETAILED DESCRIPTION OF THE INVENTION

In the following, respective embodiments of the present invention will be described while referring to the drawings. Note that the disclosure relates merely to one example, and any change readily conceived while retaining the gist of the present invention by a person skilled in the art is naturally included in the scope of the present invention. Further, in the drawings, the width, thickness, shape, etc., of the respective units may be shown schematically, compared to those according to the actual aspect, for the purpose of making the drawings clearer. The drawings merely show one example and do not limit in any way the interpretation of the present invention. In this specification and respective drawings, an element identical to one described earlier in connection with a drawing referred to earlier is given the same reference numeral, and detailed description thereof may be omitted.

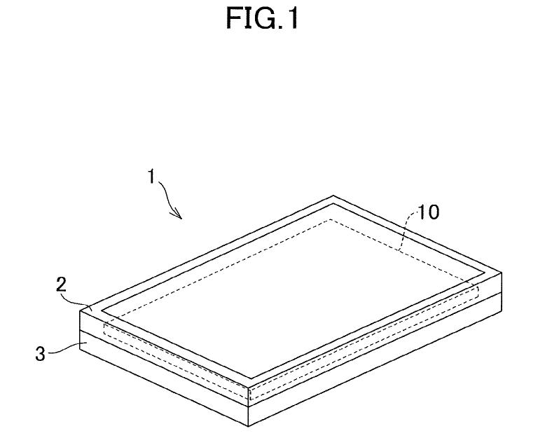

FIG. 1 is a perspective view showing an organic EL display device 1 according to an embodiment of the present invention. An organic EL display device 1 is made using an organic EL panel 10 fixedly sandwiched by an upper frame 2 and a lower frame 3. An external drive circuit (not shown) for driving the organic EL panel 10 maybe provided, together with the organic EL panel 10, inside, that is, between, the upper frame 2 and the lower frame 3, or outside via a lead wire.

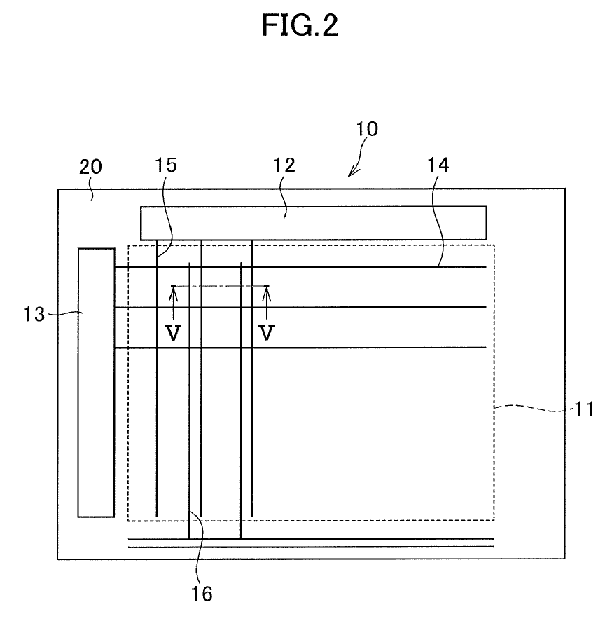

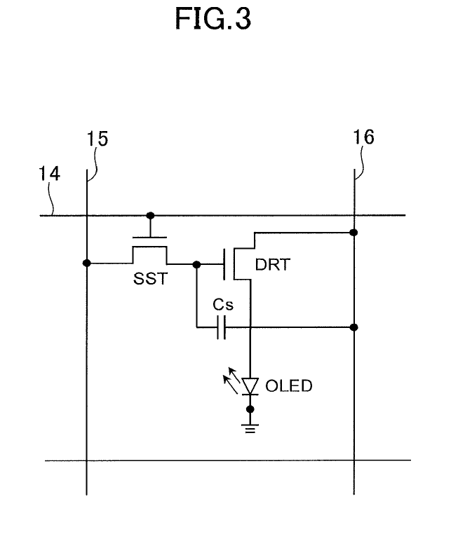

FIG. 2 is a wiring diagram of the organic EL panel 10 according to an embodiment of the present invention. FIG. 3 is a circuit diagram of a pixel of the organic EL panel 10 according to an embodiment of the present invention. The organic EL panel 10 controls respective pixels provided in a matrix in a display area 11 of a substrate 20, using a video signal driving circuit 12 and a scan signal driving circuit 13, to display an image. Note here that the video signal driving circuit 12 is a circuit for generating and sending a video signal to the respective pixels, and the scan signal driving circuit 13 is a circuit for generating and sending a scan signal to a TFT (Thin Film Transistor) provided to each pixel. Note that, although the video signal driving circuit 12 and the scan signal driving circuit 13 are arranged in two respective positions in FIG. 2, these may be built in a single IC (Integrated Circuit) or arranged separately in three or more positions.

A scan signal line 14, via which a signal from the scan signal driving circuit 13 is sent, is electrically connected to a gate of a pixel transistor SST formed in each pixel area. The scan signal line 14 is common to pixel transistors aligned in a single row. The pixel transistor SST is a transistor of which source or drain is electrically connected to the gate of a driving transistor DRT. A driving transistor DRT is, for example, an n-type channel field effect transistor, of which source is electrically connected to the anode of an organic light emitting diode OLED. The cathode of an organic light emitting diode OLED is fixed either to a ground potential or negative potential. In the above, in the organic light emitting diode OLED, a current flows from the anode to the cathode. A video signal line 15, via which a signal from the video signal driving circuit 12 is sent, is electrically connected to the source or drain of the pixel transistor SST. The video signal line 15 is common to pixel transistors aligned in one column. When a scan signal is applied to the scan signal line 14, the pixel transistor SST is turned on. When a video signal is then inputted to the video signal line 15, a video signal voltage is applied to the gate of the driving transistor DRT, whereby a voltage in accordance with the video signal is applied to a holding capacitance Cs, upon which the driving transistor DRT is turned on. A power supply line 16 is electrically connected to the drain of the driving transistor DRT. A power supply voltage for causing the organic light emitting diode OLED to emit light is applied to the power supply line 16. When the driving transistor DRT is turned on, a current in accordance with the magnitude of the video signal voltage flows into the organic light emitting diode OLED, upon which the organic light emitting diode OLED emits light.

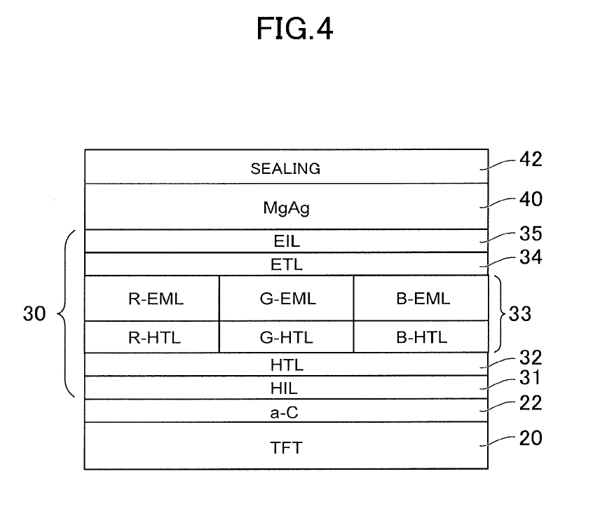

FIG. 4 is a schematic diagram showing a laminated structure of a pixel of the organic EL panel 10 according to an embodiment of the present invention. According to the organic EL panel 10 according to this embodiment, respective layers are formed on the substrate 20 on which a TFT (Thin Film Transistor), including a pixel transistor SST and a driving transistor DRT, is formed. In particular, FIG. 4 shows a layer that is formed in a process that is executed with the substrate 20 held in a vacuum environment (hereinafter referred to as a vacuum process). On the substrate 20, an amorphous carbon layer 22 (a-C), a hole injection layer 31 (HIL, a first injection layer), and a hole transport layer 32 (HTL, a first transport layer) are formed common to the respective pixels. On the hole transport layer 32, as to respective pixels that emit light in respective colors, namely, R, G, B, a light emitting layer 33 including a red hole transport layer (R-HTL) and a red light emitting layer (R-EML), a green hole transport layer (G-HTL) and a green light emitting layer (G-EML), and a blue hole transport layer (B-HTL) and a blue light emitting layer (B-EML) is formed. Further, on the light emitting layer 33, an electron transport layer (ETL, a second transport layer) 34 and an electron injection layer (EIL, a second injection layer) 35 are formed. On the electron injection layer 35, an upper electrode 40 is formed using MgAg. On the upper electrode 40, a sealing layer 42 is formed. The respective layers from the hole injection layer 31 to the electron injection layer 35 (the plurality of layers sandwiched by the amorphous carbon layer 22 and the upper electrode 40) are collectively referred to as an organic layer 30.

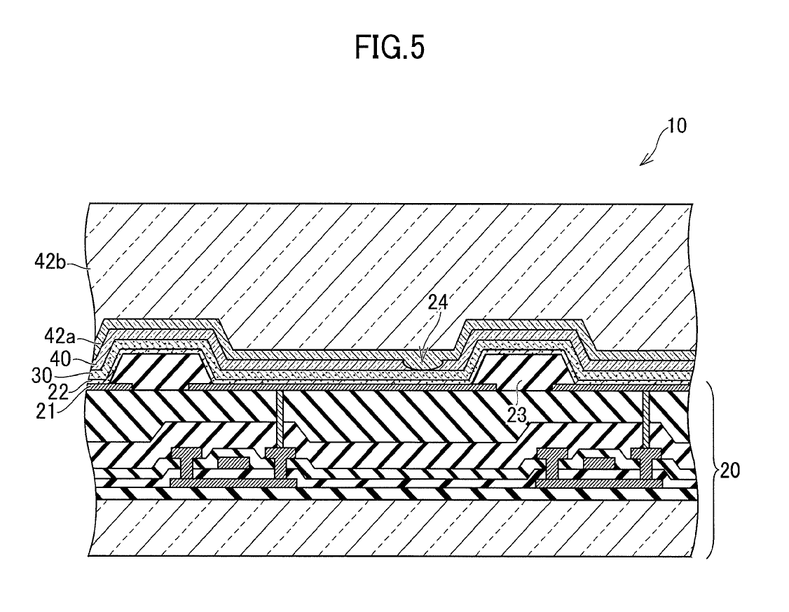

FIG. 5 is a cross sectional view of a pixel of the organic EL panel 10 according to an embodiment of the present invention. This drawing is a cross sectional view of a single pixel along the line V-V in FIG. 2. The organic EL panel 10 according to this embodiment includes a lower electrode 21 formed on the substrate 20. The lower electrode 21 is electrically connected to the source or drain of a TFT (a driving transistor DRT) formed on the substrate 20. The organic EL panel 10 includes a pixel separation film 23 formed on an end portion of the lower electrode 21 and the substrate 20 such that the middle part of the lower electrode 21 is exposed, for defining pixels. The pixel separation film 23 defines a pixel area to prevent short-circuit between the lower electrode 21 and the upper electrode 40.

The organic EL panel 10 includes an amorphous carbon layer 22 formed on the pixel separation film 23 and the part of the lower electrode 21 exposed from the pixel separation film 23. The amorphous carbon layer 22 improves adhesion of the organic layer 30. The organic EL panel 10 includes the organic layer 30 formed on the lower electrode 21 and the pixel separation film 23 and including the light emitting layer 33. Like the organic EL panel 10 according to this embodiment, the organic layer 30 is not necessarily in contact with the lower electrode 21 and the pixel separation film 23, and may be formed on the lower electrode 21 and the pixel separation film 23 via other layers such as the amorphous carbon layer 22, etc.

The organic EL panel 10 includes the upper electrode 40 formed on the organic layer 30 and the sealing layer 42 formed on the upper electrode 40. With the organic EL panel 10 according to this embodiment, the sealing layer 42 includes a first sealing layer 42a and a second sealing layer 42b. The first sealing layer 42a is a tentative sealing layer for protecting the organic layer 30, etc., in a cleaning process to be described later, and the second sealing layer 42b is a real sealing layer. The second sealing layer 42b is thicker than the first sealing layer 42a. The sealing layer 42 in this embodiment is formed by sequentially forming an SiN layer, an acrylic resin layer, and an SiN layer.

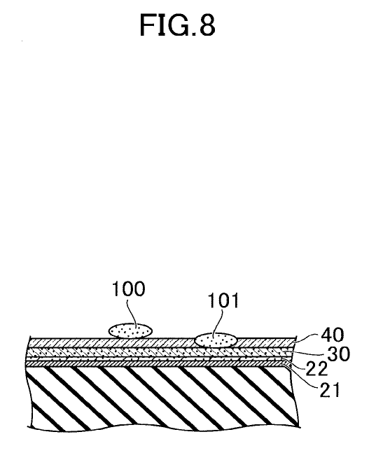

With the organic EL panel 10 according to this embodiment, at least the upper electrode 40 includes a hole 24. The hole 24 is a hole left after foreign matter has been removed, of which diameter is larger than the thickness of the upper electrode 40 and smaller than the size of the pixel area. The diameter of the hole 24 can vary depending on the diameter of foreign matter, being typically a few μm. Although the organic layer 30 immediately below the hole 24 does not contribute to light emission, as the organic layer 30 at a position other than a position immediately below the hole 24 emits light, the organic EL panel 10 as a whole can display an image with display performance equivalent to that in a case free from the hole 24. Note that although a pixel having a hole 24 is shown in FIG. 5, a hole 24 may not be formed in all pixels and there is a pixel free from a hole 24. A process in which a hole 24 is resulted will be described later in detail with reference to FIGS. 8 to 10.

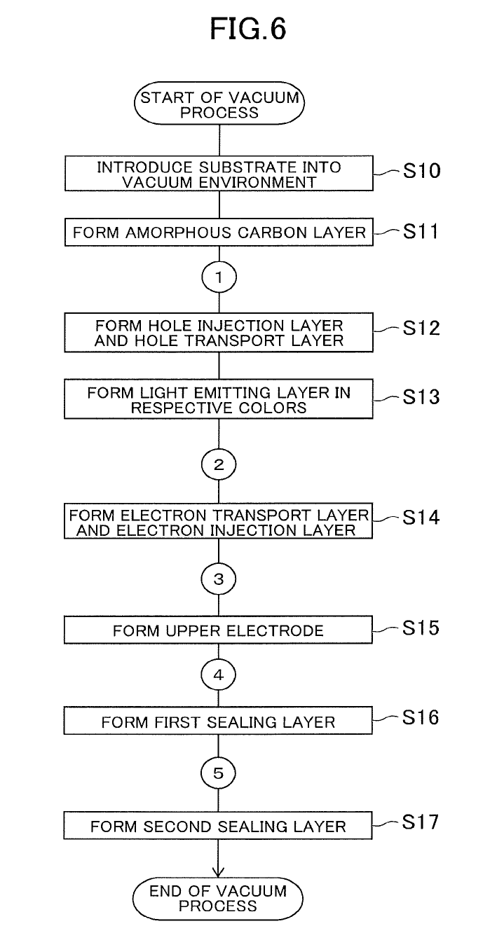

FIG. 6 is a flowchart showing a method for manufacturing the organic EL display device 1 according to an embodiment of the present invention. This drawing shows a vacuum process executed after preparation of the substrate 20 having the lower electrode 21 formed thereon.

Specifically, the vacuum process begins with a first step of placing the substrate 20 having the lower electrode 21 and the pixel separation film 23 formed thereon in a vacuum environment (S10). At this step, the substrate 20 is placed into a vacuum chamber, for example, to be thereby introduced into a vacuum environment.

After the end of the first step before the start of a second step of forming the organic layer 30, the amorphous carbon layer 22 that covers the lower electrode 21 is formed in a vacuum (S11, a fifth step). Formation of the amorphous carbon layer 22 may be executed by means of sputtering. The second step is a step of forming the organic layer 30 that includes the light emitting layer 33 and covers the lower electrode 21 in a vacuum (S12 to S14). The second step may be executed by depositing organic material. The second step begins with an A step of forming in a vacuum the hole injection layer 31 (a first injection layer) and the hole transport layer 32 (a first transport layer) that cover the lower electrode 21 (S12), and includes a B step of forming in a vacuum the light emitting layer 33 that covers the first transport layer (S13) and a C step of forming in a vacuum the electron transport layer 34 (a second transport layer) and the electron injection layer 35 (a second injection layer) that cover the light emitting layer 33 (S14). According to a method for manufacturing the organic EL display device 1 according to this embodiment, the B step of forming the light emitting layer 33 is a step of depositing the light emitting layer 33 that emits light in different colors, using a deposition mask.

A method for manufacturing the organic EL display device 1 according to this embodiment includes a cleaning process of cleaning the substrate 20 that is executed after the end of the first step (S10) before the end of a fourth step (S16 to S17) of forming the sealing layer 42. For example, the cleaning process may be executed after the end of the fifth step (S11) before the start of the second step (S12 to 14). That is, the cleaning process may be executed at the timing indicated by “1” in FIG. 6. By cleaning the substrate 20 after the end of the fifth step of forming the amorphous carbon layer 22 (S11) before the start of the second step (S12 to 14) of forming the organic layer 30, it is possible to remove foreign matter mixed when sputtering is executed, before formation of the organic layer 30 even when the amorphous carbon layer 22 is formed by means of sputtering. This can prevent foreign matter from being mixed into the organic EL display device 1, and thus to increase the yield.

Further, the cleaning process maybe executed after the end of the B step of forming the light emitting layer 33 (S13) before the start of the C step of forming the electron transport layer 34 and the electron injection layer 35 (S14). That is, the cleaning process may be executed at the timing indicated by “2” in FIG. 6. By cleaning the substrate 20 after the end of the B step of forming the light emitting layer 33 (S13) before the start of the C step of forming the electron transport layer 34 and the electron injection layer 35 (S14), it is possible to remove foreign matter even when organic material for respective light emission colors has been applied to a pixel, etc., using a deposition mask, and foreign matter has been mixed from the deposition mask. This can prevent foreign matter from being mixed into the organic EL display device 1, and thus to increase the yield.

Thereafter, a third step of forming in a vacuum the upper electrode 40 that covers the organic layer 30 is executed (S15). The cleaning process may be executed after the end of the second step (S12 to S14) of forming the organic layer 30 before the start of the third step (S15) of forming the upper electrode 40 (S15). That is, the cleaning process may be executed at the timing indicated by “3” in FIG. 6. By cleaning the substrate 20 after the end of the second step (S12 to S14) of forming the organic layer 30 before the start of the third step (S15) of forming the upper electrode 40, it is possible to collectively remove foreign matter even when foreign matter has been mixed into any of the plurality of layers constituting the organic layer 30. This can prevent foreign matter from being mixed into the organic EL display device 1, and thus to increase the yield.

Also, the cleaning process may be executed after the end of the third step (S15) of forming the upper electrode 40 before the start of the fourth step (S16 to S17) of forming the sealing layer 42. That is, the cleaning process may be executed at the timing indicated by “4” in FIG. 6. By cleaning the substrate 20 after the end of the third step (S15) of forming the upper electrode 40 before the start of the fourth step (S16 to S17) of forming the sealing layer 42, it is possible to collectively remove foreign matter even when foreign matter has been mixed into any of the plurality of layers constituting the organic layer 30. This can prevent foreign matter from being mixed into the organic EL display device 1, and thus to increase the yield.

Thereafter, the fourth step of forming in a vacuum the sealing layer 42 that covers the upper electrode 40 is executed (S16 to S17). The fourth step may be executed by means of CVD (Chemical Vapor Deposition). The fourth step includes a D step of forming in a vacuum the first sealing layer 42a that covers the upper electrode 40 (S16) and an E step of forming in a vacuum the second sealing layer 42b that covers the first sealing layer 42a (S17). The cleaning process may be executed after the end of the D step (S16) before the start of the E step (S17). That is, the cleaning process may be executed at the timing indicated by “5” in FIG. 6. In the case of a display device having flexibility, foreign matter mixed into the sealing layer 42 may deteriorate the bending tolerance of a part of the device where foreign matter is mixed, and the display device may be broken at the part. To address the above, by cleaning the substrate 20 after the end of the D step (S16) before the start of the E step (S17), it is possible to prevent foreign matter from being mixed into the first sealing layer 42a and thus to prevent breakage of the organic EL display device 1, which can increase the yield.

Note that as a typical diameter of foreign matter is a few μm, and the total of the typical thicknesses of the amorphous carbon layer 22, the organic layer 30, the upper electrode 40, and the first sealing layer 42a is a few hundreds of nm, it is expected that foreign matter protrudes from the first sealing layer 42a in any case in which the foreign matter has been mixed at any step in the vacuum process. Accordingly, it is possible to remove the foreign matter in a cleaning process even after the first sealing layer 42a has been formed.

The cleaning process may be executed at any time after the end of the first step (S10) of introducing the substrate 20 into a vacuum environment before the end of the fourth step (S16 to S17) of forming the sealing layer 42, that is, at any of the timings indicated by “1” to “5” in FIG. 6. Also, the cleaning process may be executed twice or more times at different timings.

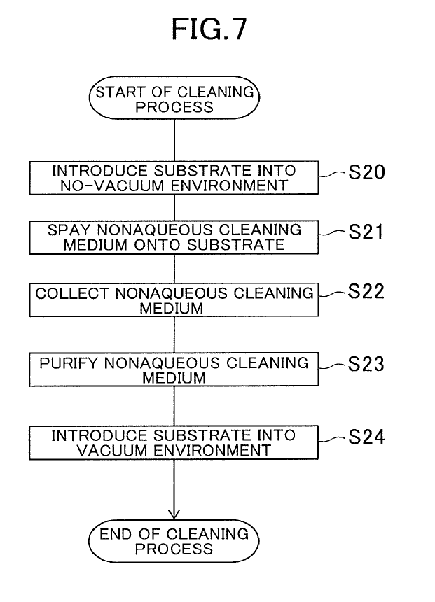

FIG. 7 is a flowchart showing a cleaning process of a method for manufacturing the organic EL display device 1 according to an embodiment of the present invention. A cleaning process is executed in a non-vacuum in the midst of the vacuum process after breaking the vacuum. The cleaning process begins with introduction of the substrate 20 into a non-vacuum environment (S20).

Then, the cleaning process is executed by spraying a nonaqueous cleaning medium onto the substrate 20 (S21). Note that a nonaqueous cleaning medium refers to a medium that does not include water as cleaning solvent. A nonaqueous cleaning medium may be any of solid, liquid, and gas. In general, use of a solid medium as a nonaqueous cleaning medium can ensure relatively strong detergency, which, however may cause relatively strong damage to the substrate 20. Meanwhile, use of liquid medium as a nonaqueous cleaning medium may result in the level of detergency and damage caused to the substrate 20 that is intermediate between those in using solid and gas solvents respectively. Use of a gas medium as a nonaqueous cleaning medium is resulted in a relatively small damage caused to the substrate 20, though the detergency is relatively weak. Specifically, the nonaqueous cleaning medium may be any of dry ice, hydrofluoroether, and nitrogen. Hydrofluoroether may be C₄F₉OCH₃, C₄F₉OC₂H₅, and C₂F₅CF (OCH₃) C₃F₇, etc. Note that the nonaqueous cleaning medium mentioned above as examples is advantageous in that the medium does not deteriorate the organic layer 30, the ozone depletion potential and global warming potential of the medium are small, and the medium can be readily handled.

The cleaning process may be executed using a gas or liquid nonaqueous cleaning medium after the start of the second step (S12 to S14) of forming the organic layer 30 before the start of the fourth step (S16 to S17) of forming the sealing layer 42. In the case where the cleaning process is executed after the start of the second step (S12 to S14) of forming the organic layer 30 before the start of the fourth step (S16 to S17) of forming the sealing layer 42, the organic layer 30, which is very vulnerable to damage, is brought into direct contact with the nonaqueous cleaning medium. Therefore, by using a gas or liquid nonaqueous cleaning medium, it is possible to ensure a relatively small damage caused to the organic layer 30, while removing foreign matter mixed into the organic layer 30.

The cleaning process may include an F step of collecting the nonaqueous cleaning medium having been sprayed onto the substrate 20 (S22) and purifying the medium collected (S23). With the above, even when a relatively expensive medium is used as a nonaqueous cleaning medium, the cleaning process is achieved at lower cost.

Finally, the substrate 20 having been cleaned is introduced into a vacuum environment (S24) to end the cleaning process. After the end of the cleaning process, the vacuum process having been stopped halfway is resumed.

FIG. 8 shows first foreign matter 100 and second foreign matter 101 to be removed according to a method for manufacturing the organic EL display device 1 according to the present invention. The first foreign matter 100 is mixed after formation of the upper electrode 40 and stays on the upper electrode 40. Meanwhile, the second foreign matter 101 is mixed after formation of the organic layer 30 before formation of the upper electrode 40 and is embedded in the upper electrode 40. Note that the first foreign matter 100 and the second foreign matter 101 are mere examples, and foreign matter may be mixed in any other condition or no foreign matter may be mixed at all.

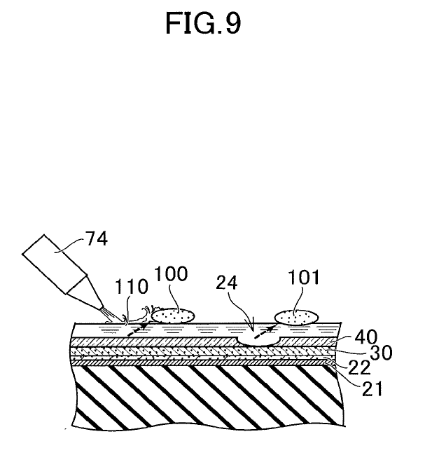

FIG. 9 shows a cleaning process of a method for manufacturing the organic EL display device 1 according to an embodiment of the present invention. Specifically, FIG. 9 shows a cleaning process that is executed at the timing indicated by “4” in FIG. 6, using a nonaqueous cleaning medium 110 that is liquid. The nonaqueous cleaning medium 110 is sprayed onto the surface of the upper electrode 40 by a spray nozzle 74. The first foreign matter 100 and the second foreign matter 101 are blown by the nonaqueous cleaning medium 110 sprayed. FIG. 9 shows the first foreign matter 100 and the second foreign matter 101 being blown. After the second foreign matter 101 is blown, a hole 24 is left on the upper electrode 40.

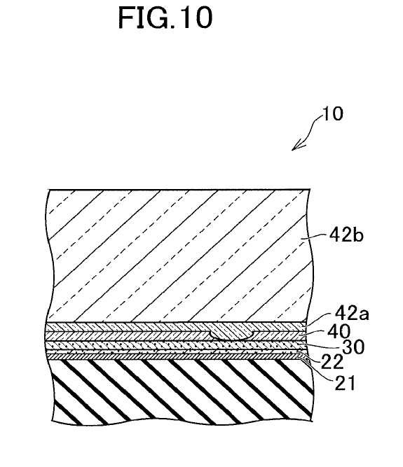

FIG. 10 is a cross sectional view of the organic EL panel 10 according to an embodiment of the present invention. FIG. 10 shows the first sealing layer 42a and the second sealing layer 42b that are formed after the first foreign matter 100 and the second foreign matter 101 has been removed in the cleaning process.

The first sealing layer 42a is filled in the hole 24 resulted on the upper electrode 40, so that the organic layer 30 can be prevented from being exposed. As described above, a structure of the organic EL panel 10 according to this embodiment shown in FIG. 5 is formed.

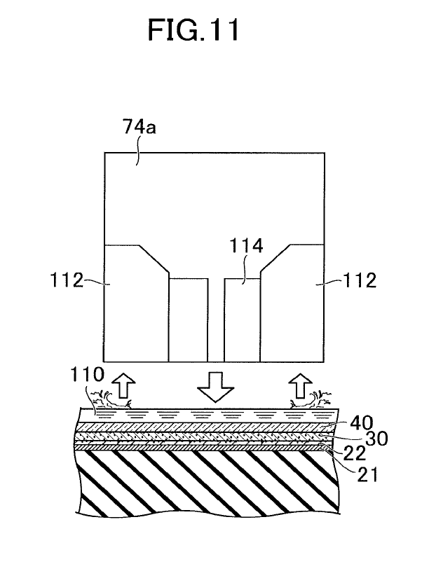

FIG. 11 is a schematic diagram showing the first spray nozzle 74a used in the cleaning process of a method for manufacturing the organic EL display device 1 according to an embodiment of the present invention. The first spray nozzle 74a includes a sucking port 112 for sucking the nonaqueous cleaning medium 110 sprayed and foreign matter, and a spraying port 114 for spraying a nonaqueous cleaning medium. The spraying port 114 includes a supersonic wave oscillator for finely vibrating the nonaqueous cleaning medium to enhance cleaning effect. Note that although a case in which a liquid nonaqueous cleaning medium is sprayed is shown in FIG. 11, either a solid or gas nonaqueous cleaning medium may be sprayed, depending on the first spray nozzle 74a.

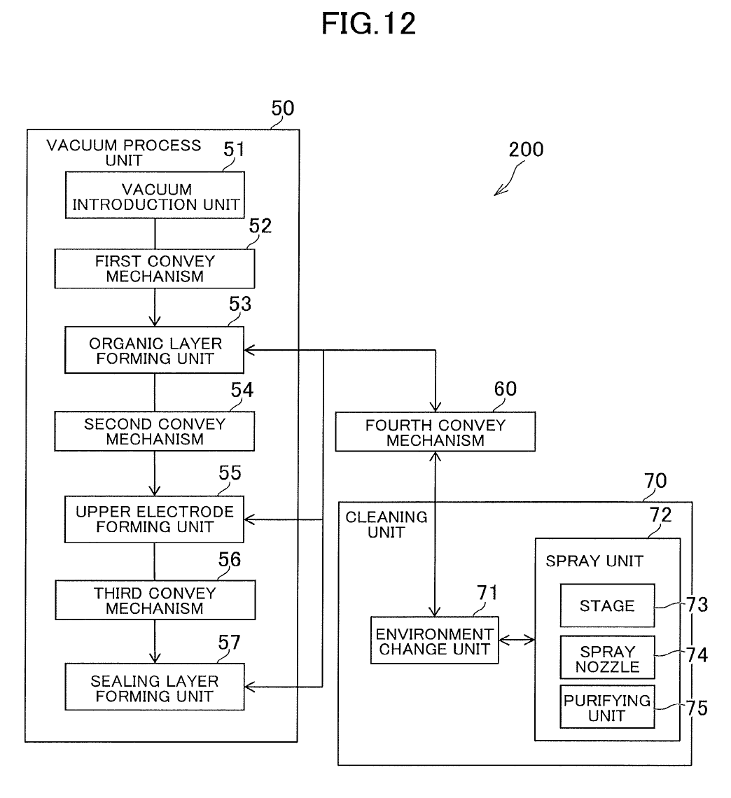

FIG. 12 is a block diagram showing a structure of a manufacturing apparatus 200 for the organic EL display device 1 according to an embodiment of the present invention. The manufacturing apparatus 200 for the organic EL display device 1 includes a vacuum process unit 50, a cleaning unit 70, and a fourth convey mechanism 60 for connecting the vacuum process unit 50 and the cleaning unit 70.

The vacuum process unit 50 includes a vacuum introduction unit 51 for introducing vacuum into the environment where the substrate 20 having the lower electrode 21 formed thereon is placed. The vacuum introduction unit 51 includes a chamber for accommodating the substrate 20 having the lower electrode 21 formed thereon, and vacuums the inside of the chamber to thereby place the substrate 20 in a vacuum environment. The structure included in the vacuum process unit 50 to be described below is arranged in the vacuum chamber.

The vacuum process unit 50 includes an organic layer forming unit 53 connected to the vacuum introduction unit 51 via a first convey mechanism 52, for forming in a vacuum the organic layer 30 including the light emitting layer 33 and covering the lower electrode 21 on the substrate 20. Note here that the first convey mechanism 52 is placed in the vacuum chamber and conveys the substrate 20. Specifically, the first convey mechanism 52 is a belt conveyer or a robot arm.

The vacuum process unit 50 includes an upper electrode forming unit 55 connected to the organic layer forming unit 53 via a second convey mechanism 54, for forming in a vacuum the upper electrode 40 covering the organic layer 30. Further, the vacuum process unit 50 includes a sealing layer forming unit 57 connected to the upper electrode forming unit 55 via a third convey mechanism 56, for forming in a vacuum the sealing layer 42 covering the upper electrode 40. Note here that each of the second convey mechanism 54 and the third convey mechanism 56 has a structure similar to that of the first convey mechanism 52, and is placed in a vacuum chamber.

The cleaning unit 70 is connected to at least one of the organic layer forming unit 53, the upper electrode forming unit 55, and the sealing layer forming unit 57 via the fourth convey mechanism 60 to clean the substrate 20. In the manufacturing apparatus 200 for the organic EL display device 1 according to the embodiment, the cleaning unit 70 is connected to the organic layer forming unit 53, the upper electrode forming unit 55, and the sealing layer forming unit 57 via the fourth convey mechanism 60, and the fourth convey mechanism 60 selects a distribution designation. The fourth convey mechanism 60 has a structure similar to that of the first convey mechanism 52 and is placed in the vacuum chamber.

According to the manufacturing apparatus 200 for the organic EL display device 1 according to the embodiment, it is possible to insert a cleaning process executed in a non-vacuum into the midst of the vacuum process without deteriorating the vacuum environment for the vacuum process. With the above, it is possible to execute a cleaning process before foreign matter is sealed in the sealing layer 42.

The cleaning unit 70 includes an environment change unit 71 connected to the fourth convey mechanism 60, for changing a vacuum environment into a carbon dioxide-filled environment or a nitrogen-filled environment, and a carbon dioxide-filled environment or a nitrogen-filled environment into a vacuum environment, and a spray unit 72 connected to the environment change unit 71, for spraying a nonaqueous cleaning medium onto the substrate 20. Before the cleaning process is executed, the environment change unit 71 receives the substrate 20 from the fourth convey mechanism 60 in a vacuum environment, and thereafter, changes the vacuum environment to either the carbon dioxide-filled environment or the nitrogen-filled environment. Note that in using dry ice as a nonaqueous cleaning medium, the environment change unit 71 changes the vacuum environment into a carbon dioxide-filled environment, and in using hydrofluoroether or nitrogen as a nonaqueous cleaning medium, the environment change unit 71 changes the vacuum environment into a nitrogen-filled environment. Then, after completion of the cleaning process, the environment change unit 71 changes the carbon dioxide-filled environment or the nitrogen-filled environment into a vacuum environment before returning the substrate 20 to the fourth convey mechanism 60.

The spray unit 72 includes a stage 73, a spray nozzle 74, and a purifying unit 75. A specific structure of the spray unit 72 will be described in detail with reference to the next drawing.

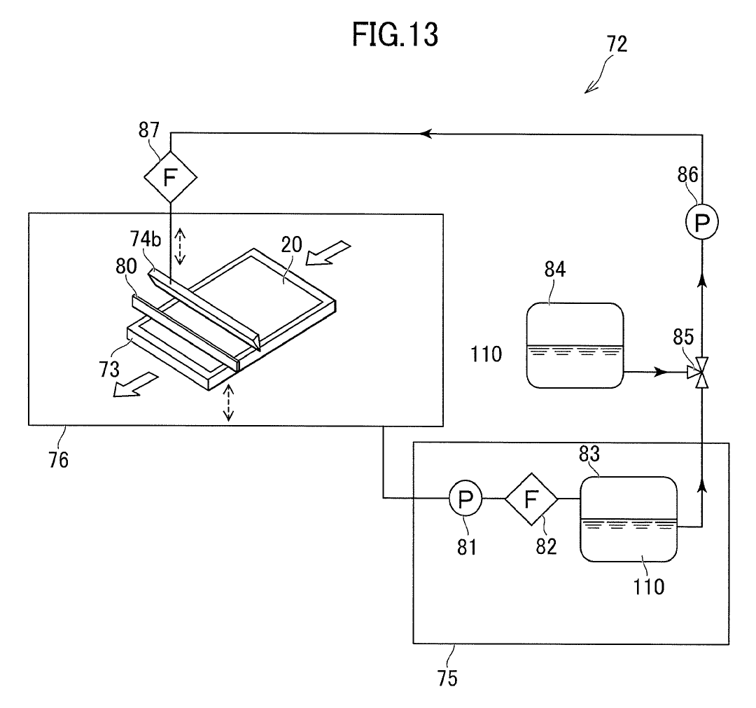

FIG. 13 is a schematic diagram showing the spray unit 72 of the manufacturing apparatus 200 for the organic EL display device 1 according to an embodiment of the present invention. The spray unit 72 includes a cleaning chamber 76 for receiving and cleaning the substrate 20, using the nonaqueous cleaning medium 110, and the purifying unit 75 for collecting and purifying the nonaqueous cleaning medium 110. The cleaning chamber 76 of the spray unit 72 includes the stage 73 for holding the substrate 20 inclined. In the case of a nonaqueous cleaning medium 110 that is liquid, when the substrate 20 is held inclined by the stage 73, the nonaqueous cleaning medium sprayed onto the substrate 20 runs down from the stage 73 so that the nonaqueous cleaning medium 110 can be readily collected.

The cleaning chamber 76 includes a second spray nozzle 74b and an ionizer 80. The second spray nozzle 74b sprays the nonaqueous cleaning medium 110 onto the substrate 20. The second spray nozzle 74b can change the distance to the substrate 20. As it is possible to change the distance from the second spray nozzle 74b to the substrate 20, it is possible to keep constant the distance between the second spray nozzle 74b and the substrate 20 even when the stage 73 is inclined. The second spray nozzle 74b is provided traversing the substrate 20. Note here that the substrate 20 may include a part that makes a plurality of display panels, which maybe cut out by dicing into display panels. With he second spray nozzle 74b traversing the substrate 20, the cleaning process can be executed with high efficiency.

The ionizer 80 removes electric charge from the substrate 20. With the nonaqueous cleaning medium 110 sprayed onto the substrate 20, electric charge of a few kV may be generated. Removing the electric charge by the ionizer 80 can prevent occurrence of defect in subsequent layer formation.

The purifying unit 75 is connected to the cleaning chamber 76, and collects and purifies the nonaqueous cleaning medium 110 sprayed onto the substrate 20. The purifying unit 75 collects the nonaqueous cleaning medium 110 used and accumulated in the cleaning chamber 76, using a circulation pump 81, and purifies the nonaqueous cleaning medium 110 collected, using a filtration filter 82. The purifying unit 75 may distill to thereby purify the nonaqueous cleaning medium 110 collected. The nonaqueous cleaning medium 110 purified is stored in a recycling tank 93. As the nonaqueous cleaning medium 110 is recycled, as described above, the cleaning process can be executed at lower cost compared to a case where the nonaqueous cleaning medium 110 is used once and then disposed.

The spray unit 72 includes a new material tank 84, in which unused nonaqueous cleaning medium 110 is stored. A switch valve 85 switches to connect a feeding pump 86 to either the new material tank 84 or a recycle tank 83. The nonaqueous cleaning medium 110 is sent to a final filter 87 via the feeding pump 86, and the nonaqueous cleaning medium 110 filtered is sprayed onto the substrate 20 by the second spray nozzle 74b.

Note that all display devices that can be achieved through desirable change in design by a person skilled in the art based on the display device 1 described above as an embodiment of the present invention are included in the scope of the present invention as long as such display devices contain the gist of the present invention. For example, while the organic EL panel 10 according to this embodiment has the light emitting layer 33 for emitting light in respective R, G, B colors formed thereon, the present invention can be applied to a display device in which a light emitting layer for emitting light in white color is formed and a color filter is provided on the sealing layer 42 to therewith achieve full-color display. Further, while the nonaqueous cleaning medium 110 is sprayed onto the substrate 20 to clean the substrate 20 in the manufacturing apparatus 200 for manufacturing the organic EL display device 1 according to this embodiment, the substrate 20 may be dipped in the nonaqueous cleaning medium 110 to be cleaned.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A method for manufacturing a display device, the method comprising:
placing a substrate having a lower electrode formed thereon in a vacuum environment, as a first step;
forming an organic layer that includes a light emitting layer and covers the lower electrode in a vacuum environment, as a second step;
forming an upper electrode that covers the organic layer in a vacuum environment, as a third step;
forming a sealing layer that covers the upper electrode in a vacuum environment, as a fourth step; and
cleaning the substrate after end of the first step before end of the fourth step, as a cleaning step.

2. The method according to claim 1, wherein
the second step includes
an A step of forming a first injection layer and a first transport layer that cover the lower electrode in a vacuum environment,
a B step of forming a light emitting layer that covers the first transport layer in a vacuum environment, and
a C step of forming a second transport layer and a second injection layer that cover the light emitting layer in a vacuum environment, and
the cleaning step is executed after end of the B step before start of the C step.

3. The method according to claim 2, wherein the B step is a step of depositing a light emitting layer that emits light in different colors, using a deposition mask.

4. The method according to claim 1, wherein the cleaning step is executed after end of the second step before start of the third step.

5. The method according to claim 1, wherein the cleaning step is executed after end of the third step before start of the fourth step.

6. The method according to claim 1, further comprising a fifth step of forming an amorphous carbon layer that covers the lower electrode in a vacuum environment after the end of the first step before start of the second step, wherein
the cleaning step is executed after end of the fifth step before start of the second step.

7. The method according to claim 1, wherein
the fourth step includes
a D step of forming a first sealing layer that covers the upper electrode in a vacuum environment, and
an E step of forming a second sealing layer that covers the first sealing film in a vacuum environment, and
the cleaning step is executed after end of the D step before start of the E step.

8. The method according to claim 1, wherein the cleaning step is executed by spraying a nonaqueous cleaning medium onto the substrate.

9. The method according to claim 8, wherein the cleaning step includes an F process of collecting and purifying the nonaqueous cleaning medium sprayed onto the substrate.

10. The method according to claim 8, wherein
the nonaqueous cleaning medium is gas or liquid, and
the cleaning step is executed after start of the second step before start of the fourth step.

11. The method according to claim 8, wherein the nonaqueous cleaning medium is any of dry ice, hydrofluoroether, and nitrogen.

12. The method according to claim 1, wherein the cleaning step is executed in a non-vacuum.

13. A display device, comprising:
a substrate;
a plurality of pixels formed on the substrate;
a lower electrode provided to each of the plurality of pixels;
a pixel separation film formed on the substrate, configured to cover an end portion of the lower electrode so as to leave a middle part of the lower electrode exposed, and configured to define the plurality of pixels;
an organic layer being in contact with the portion of the lower electrode exposed from the pixel separation film, positioned on the pixel separation film, and including a light emitting layer;
an upper electrode formed on the organic layer; and
a sealing layer formed on the upper electrode, wherein
the upper electrode has a hole formed on a surface thereof in contact with the sealing layer.

14. An apparatus for manufacturing a display device, comprising:
a vacuum introduction unit for placing a substrate having a lower electrode formed thereon in a vacuum environment;
an organic layer forming unit connected to the vacuum introduction unit via a first convey mechanism, for forming an organic layer that includes a light emitting layer and covers the lower electrode on the substrate in a vacuum environment;
an upper electrode forming unit connected to the organic layer forming unit via a second convey mechanism, for forming an upper electrode that covers the organic layer in a vacuum environment;
a sealing layer forming unit connected to the upper electrode forming unit via a third convey mechanism, for forming a sealing layer that covers the upper electrode in a vacuum environment; and
a cleaning unit connected to at least one of the organic layer forming unit, the upper electrode forming unit, and the sealing layer forming unit via a fourth convey mechanism, for cleaning the substrate.

15. The apparatus according to claim 14, wherein
the cleaning unit includes
an environment change unit connected to the fourth convey mechanism, for changing a vacuum environment into a carbon dioxide-filled environment or a nitrogen-filled environment, and a carbon dioxide-filled environment or a nitrogen-filled environment into a vacuum environment, and
a spraying unit connected to the environment change unit, for spraying a nonaqueous cleaning medium onto the substrate.

16. The apparatus according to claim 15, wherein the spraying unit includes a stage for holding the substrate inclined.

17. The apparatus according to claim 15, wherein the spraying unit includes a spray nozzle capable of changing a distance to the substrate, for spraying the nonaqueous cleaning medium onto the substrate.

18. The apparatus according to claim 15, wherein the spraying unit includes a purifying unit for collecting and purifying the nonaqueous cleaning medium sprayed onto the substrate.

19. The apparatus according to claim 14, wherein the spraying unit includes an ionizer for removing electric charge from the substrate.
